(19) United States
(12) Patent Application Publication
(10) Pub. No.: US 2006/0187643 A1
(43) Pub. Date: Aug. 24, 2006

(54) Heat dissipation device and heat dissipation method for electronic equipment

(75) Inventor: Hideo Tsurufusa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/348,476

(22) Filed: Feb. 7, 2006

(30) Foreign Application Priority Data
Feb. 18, 2005 (JP) 2005-042344

(51) Int. Cl. H05K 7/20

(52) U.S. Cl. 361/704

(57) ABSTRACT

According to one embodiment, fixing plates are formed to a shield case which covers a circuit board including a circuit component. When a heat sink, which has bent heat dissipation plates and can be accommodated in a shield case, is attached to the fixing plates and the surface of the circuit board is covered by the shield case, the heat sink comes into contact with the heat conduction sheet attached to the circuit component.

### CROSS-REFERENCE TO RELATED APPLICATIONS

This application is based upon and claims the benefit of priority from Japanese Patent Application No. 2005-042344, filed Feb. 18, 2005, the entire contents of which are incorporated herein by reference.

### BACKGROUND

1. Field

One embodiment of the invention relates to electronic equipment, for example, a digital-television broadcasting receiver and the like, and a more particularly, to a heat dissipation device and a heat dissipation method for dissipating heat from heat generating circuit components.

2. Description of the Related Art

As known well, in recent years, digitalization of television broadcasting is promoted. For example, in Japan, ground digital broadcasting starts in addition to satellite digital broadcasting such as BS (broadcasting satellite) digital broadcasting, 110° CS (communication satellite) digital broadcasting, and the like.

In digital broadcasting receivers for receiving such digital television broadcasting, since it is required to process, in particular, digital video data at high speed, a circuit component such as an LSI (large scale integration) and the like that execute the high speed processing generates heat. Thus, it is vital to employ a countermeasure for dissipated heat.

Jpn. Pat. Appln. KOKAI Publication No. 9-64582 discloses an arrangement that a hole is formed in a flat surface of a shield case that is parallel to the surface of a circuit board, and a metal distinct piece is attached to the peripheral edge portion of the hole so as to come into contact with a heat generating component mounted on the circuit board. In this case, the metal distinct piece is attached to the shield case in such a manner that the peripheral edge portion of the hole is clamped in the direction of thickness by a pair of projections projecting from the metal distinct piece in parallel to the flat surface of the shield case.

U.S. Pat. No. 6,445,583 also discloses an arrangement that a hole is formed to a flat surface parallel to a surface of a circuit board of a shield case and a lid member, which comes into contact with a heat generating component mounted on the circuit board, is attached to the peripheral edge portion of the hole. In this case, the lid member is attached to the peripheral edge portion of the hole by a cam structure using elastic force.

U.S. Pat. No. 5,060,114 discloses an arrangement that a heat generating component is caused to come into contact with a heat sink acting also as a shield case through a flexible gel-like pad. In this case, the heat sink is caused to come into pressure contact with the heat generating component by the elastic force generated by the heat sink itself. Jpn. Pat. Appln. KOKAI Publication No. 2002-359330 and U.S. Pat. No. 5,384,940 disclose an arrangement that a heat dissipating member is caused to come into pressure contact with a heat generating component by a leaf spring or a coil spring.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block arrangement view that shows an embodiment of the present invention and explains a video signal processing system of a television broadcasting receiver;

FIG. 2 is an exploded perspective view explaining a circuit board on which the video signal processing system in the embodiment is arranged and structures of a heat sink and a shield case;

FIG. 3 is a side sectional view explaining an attachment structure of the heat sink and the shield case in the embodiment;

FIG. 4 is an exploded perspective view shown to explain a modification of the structure of the shield case in the embodiment;

FIG. 5 is a side sectional view shown to explain a modification of a shape of a heat dissipation plate of the heat sink in the embodiment;

FIG. 6 is a side sectional view shown to explain another modification of the heat dissipation plate of the heat sink in the embodiment;

FIG. 7 is a side sectional view shown to explain still another modification of the heat dissipation plate of the heat sink in the embodiment; and

FIG. 8 is a side sectional view shown to explain a further modification of the heat dissipation plate of the heat sink in the embodiment.

### DETAILED DESCRIPTION

Various embodiments according to the invention will be described hereinafter with reference to the accompanying drawings. In general, according to one embodiment of the invention, fixing plates are formed to a shield case which covers a circuit board including a circuit component. When a heat sink, which has bent heat dissipation plates and can be accommodated in a shield case, is attached to the fixing plates and the surface of the circuit board is covered by the shield case, the heat sink comes into contact with the heat conduction sheet attached to the circuit component.

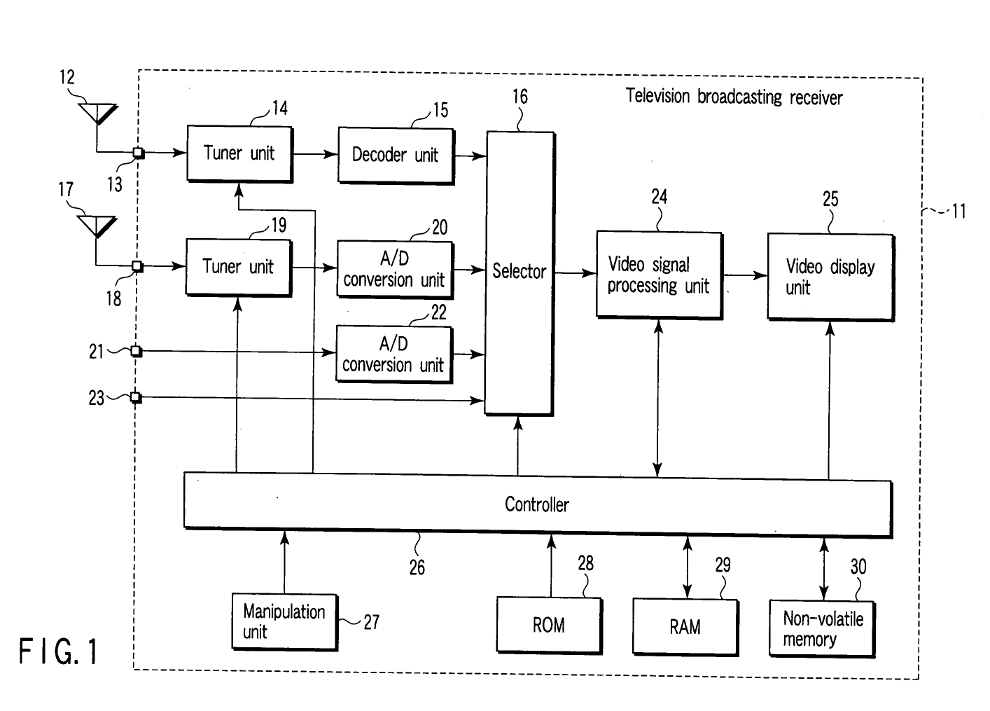

An embodiment of the present invention will be explained below in detail with reference to the drawings. FIG. 1 schematically shows a video signal processing system of a television broadcasting receiver 11 explained in the embodiment. More specifically, a digital television broadcasting signal received by an antenna 12 for receiving digital television broadcasting is supplied to a tuner unit 14 through an input terminal 13.

The tuner unit 14 selects and demodulates the signal of a desired channel from the digital television broadcasting signal input thereto. The signal output from the tuner unit 14 is supplied to a decoder unit 15, subjected to, for example, MPEG (moving picture experts group) 2 decode processing therein, and then supplied to a selector 16.

Further, an analog television broadcasting signal received by an antenna 17 for receiving analog television broadcasting is supplied to a tuner unit 19 through an input terminal 18. The tuner 19 selects and demodulates the signal of a desired channel from the analog television broadcasting signal input thereto. The signal output from the tuner unit 19 is output to the selector 16 after it is digitized by an A/D (analog/digital) conversion unit 20.

Further, an analog video signal supplied to an external input terminal 21 for analog video signal is output to the selector 16 after it is supplied to an A/D conversion unit 22 to be digitized. Further, a digital video signal supplied to an external input terminal 23 for digital video signal is supplied to the selector 16 as it is.

The selector 16 selects one of the four types of digital video signals input thereto and supplies it to a video signal processing unit 24. The video signal processing unit 24 subjects the digital video signal input thereto to predetermined signal processing so that it is displayed on a video display unit 25. Employed as the video display unit 25 is a flat panel display composed of, for example, a liquid crystal display, a plasma display, and the like.

In the television broadcasting receiver 11, various types of operations including the various types of the signal receiving operations described above are integrally controlled by a controller 26. The controller 26 is composing a microprocessor including a CPU (central processing unit) and controls the respective units in response to manipulation information from a manipulation unit 27 including a remote controller (not shown) and the like so that the manipulation contents of the manipulation information are reflected.

In this case, the controller 26 mainly makes use of a ROM (read only memory) 28 in which a control program to be executed by the CPU is stored, a RAM (random access memory) 29 for providing the CPU with a working area, and a non-volatile memory 30 in which various types of setting information, control information, and the like are stored.

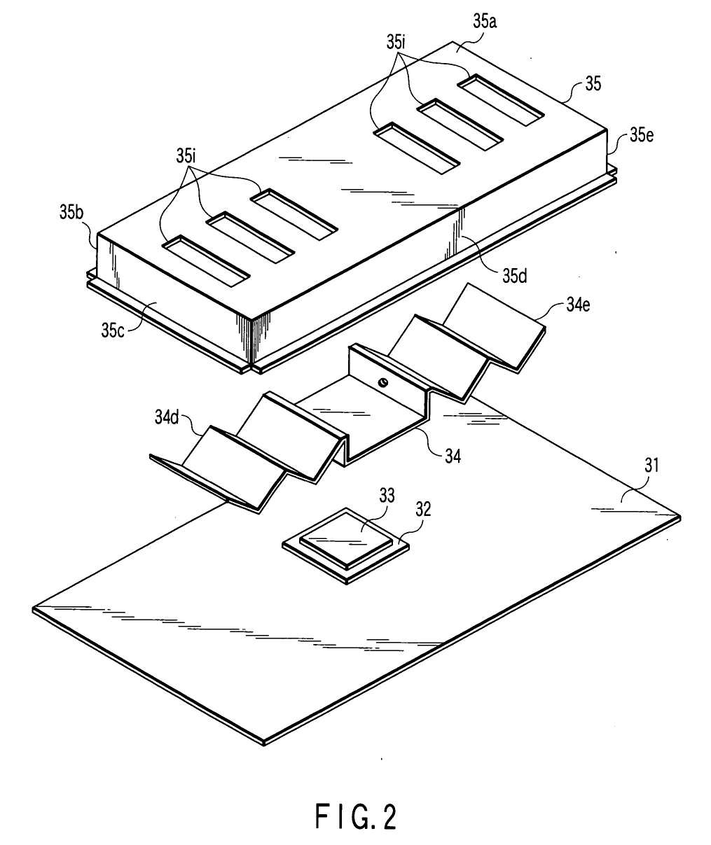

FIG. 2 shows a circuit board 31 on which the video signal processing system of the television broadcasting receiver 11 is arranged. That is, various types of circuit components, circuit patterns, and the like for constituting the video signal processing system are mounted on circuit board 31. A countermeasure for heat dissipation is required to, in particular, an LSI 32 constituting the decoder unit 15 in the various types of the circuit components mounted on the circuit board 31 because the LSI 32 generates heat when it processes digital data at high speed.

As the countermeasure for heat dissipation, a heat sink 34 is caused to come into intimate contact with the surface of the LSI 32 which is formed in an approximately square flat shape, located opposite to the surface thereof confronting the circuit board 31 through a flexible heat conduction sheet 33. Then, various types of circuit component are electromagnetically shielded by covering the surface of the circuit board 31, on which the LSI 32 is mounted, by a shied case 35 together with the heat sink 34.

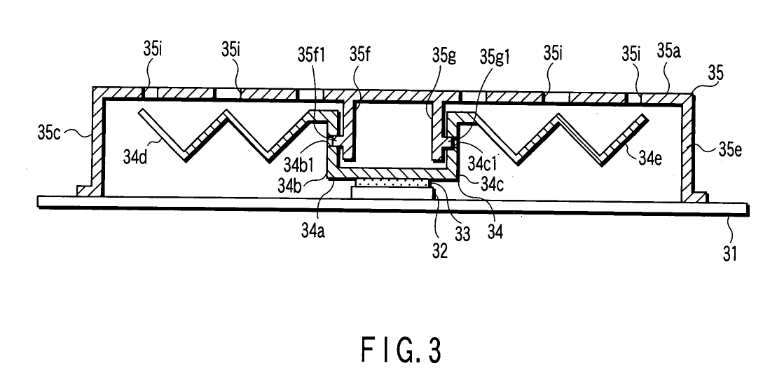

FIG. 3 shows an attachment structure of the heat sink 34. The heat sink 34 is composed of a base plate 34a formed in an approximately square flat shape, a pair of side plates 34b and 34c extending from both confronting ends of the base plate 34a vertically in the same direction with respect to the surface of the base plate 34a, and heat dissipation plates 34d and 34e extending externally from the apical ends of the side plates 34b and 34c, respectively, and these members are formed integrally with each other by press-molding, for example, a metal material and the like having a heat conduction property. Then, locking holes 34b1 and 34c1 are formed to predetermined positions confronting each other of the pair of side plates 34b and 34c of the heat sink 34.

Further, the shield case 35 is composed of a flat plate 35a formed in an approximately square flat shape, four side plates 35b, 35c, 35d, and 35e extending from the four peripheral edge portions of the flat plate 35a in the same direction vertically with respect to the surface of the flat plate 35a, respectively, and two fixing plates 35f and 35g projecting from predetermined positions of the flat plate 35a so as to respectively confront the surfaces of side plates 34b and 34c of the heat sink 34, and these members are formed integrally with each other by extrusion molding, for example, a metal material and the like.

The shield case 35 covers various types of circuit components mounted on the circuit board 31 by being attached to the circuit board 31 such that the opening end thereof formed by the respective side plates 35b, 35c, 35d, and 35e come into contact with the surface of the circuit board 31.

Further, projecting portions 35f1 and 35g1, which can be engaged with the locking holes 34b1 and 34c1 formed to the side plates 34b and 34c, are formed to the respective fixing plates 35f and 35g of the shield case 35.

Accordingly, the heat sink 34 can be combined integrally with the shield case 35 by engaging the projecting portions 35f1 and 35g1 formed to the fixing plates 35f and 35g of the shield case 35 with the locking holes 34b1 and 34c1 formed to the side plates 34b and 34c of the heat sink 34, respectively. The base plate 34a of the heat sink 34 is caused to come into intimate contact with the heat conduction sheet 33 at predetermined pressure by attaching the shield case 35 to the circuit board 31 in this state, thereby a heat dissipation structure is completed.

The heat dissipation plates 34d and 34e of the heat sink 34 extend externally each other from the ends of the side plates 34b and 34c opposite to the ends where the base plate 34a is formed, that is, in opposite directions. The respective heat dissipation plates 34d and 34e are bent in a triangular wave shape so that they can be accommodated in the shield case 35 when the shield case 35 is attached to the circuit board 31. With this arrangement, the respective heat dissipation plates 34d and 34e can increase the surface areas thereof in the shield case 35, thereby a heat dissipation effect can be enhanced.

Further, the flat plate 35a of the shield case 35 has clearance holes 35i formed to the portions where the heat dissipation plates 34d and 34e bent in the triangular wave shape are in the vicinities thereof. With this arrangement, the heat dissipation effect can be enhanced.

According to the embodiment described above, when the shield case 35 is combined integrally with the heat sink 34 and the shield case 35 is attached to the circuit board 31, the heat sink 34 comes into intimate contact with the heat conduction sheet 33. Therefore, an arrangement for causing the heat sink 34 to come into pressure contact with the LSI 32 using a leaf spring, a coil spring, and the like is not necessary, thereby the heat dissipation effect can be sufficiently obtained by a simple arrangement.

Further, the surface areas of the heat dissipation plates 34d and 34e of the heat sink 34 are increased by bending them in the triangular wave shape in the state that they are accommodated in the shield case 35 as well as the clearance holes 35i are formed to the portions of the flat plate 35a of the shield case 35 where the heat dissipation plates 34d and 34e are in the vicinities thereof, thereby the heat dissipation effect can be enhanced by the simple arrangement without sacrificing a shield effect.

Further, since the projecting portions 35f1 and 35g1 of the fixing plates 35f and 35g projecting vertically from the flat plate 35a of the shield case 35 are engaged with the locking holes 34b1 and 34c1 formed to the side plates 34b and 34c of the heat sink 34, a member for attaching the heat sink 34 to the shield case 35 does not project externally from the flat plate 35a of the shield case 35, which also contributes to simplify and miniaturize the arrangement.

Note that although the locking holes 34b1 and 34c1 are formed to the side plates 34b and 34c of the heat sink 34 and the projecting portions 35f1 and 35g1 are formed to the fixing plates 35f and 35g of the shield case 35 in the embodiment described above, the present invention is by no means limited thereto, and it is needless to say that the projecting portions may be formed to the side plates 34b and 34c of the heat sink 34 and the locking holes may be formed to the fixing plates 35f and 35g of the shield case 35.

It is also needless to say that the locking holes 34b1 and 34c1 need not be holes passing through the side plates 34b and 34c and may be recessed portions with which the projecting portions 35f1 and 35g1 can be engaged.

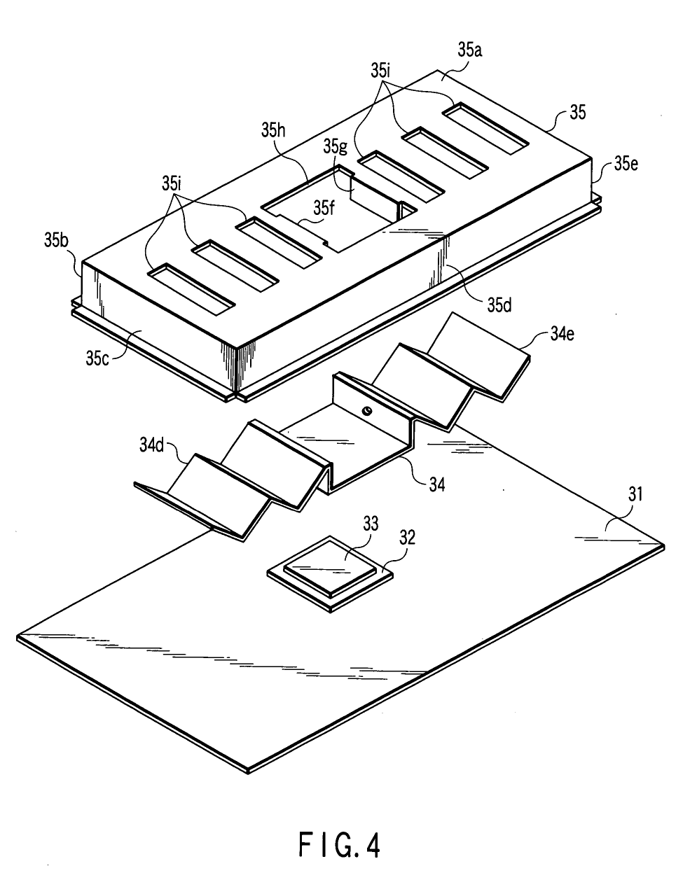

Further, as shown in FIG. 4, a cutout portion 35h may be formed to the portion of the flat plate 35a of the shield case 35 which corresponds to the attachment position of the heat sink 34 while remaining a part of the flat plate 35a, and the fixing plates 35f and 35g may be formed by bending the remaining part of the remaining flat plate 35a vertically. With this arrangement, since the heat sink 34 is exposed to the outside through the cutout portion 35h, the heat dissipation effect can be enhanced.

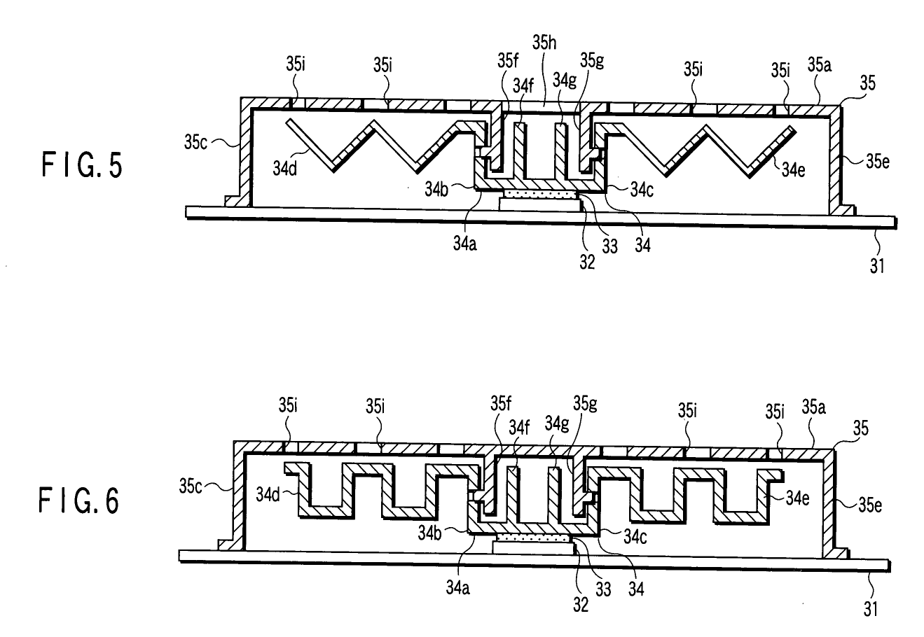

Further, in the arrangement in which the cutout portion 35h is formed to the flat plate 35a of the shield case 35, when a plurality (two pieces in the illustrated example) of heat dissipation plates 34f and 34g, which project from predetermined positions of the base plate 34a of the heat sink 34 parallel to the side plates 34b and 34c, are formed by, for example, extrusion molding and the like as shown in FIG. 5, the heat dissipation effect can be more enhanced.

FIGS. 6 to 8 show modifications of the heat dissipation plates 34d and 34e, respectively. First, FIG. 6 shows a state that the heat dissipation plates 34d and 34e are bent in a rectangular wave shape, respectively. In this case, when the clearance holes 35i are formed to the portions of the flat plate 35a of the shield case 35 where the heat dissipation plates 34d and 34e are in the vicinities thereof, the heat dissipation effect can be enhanced.

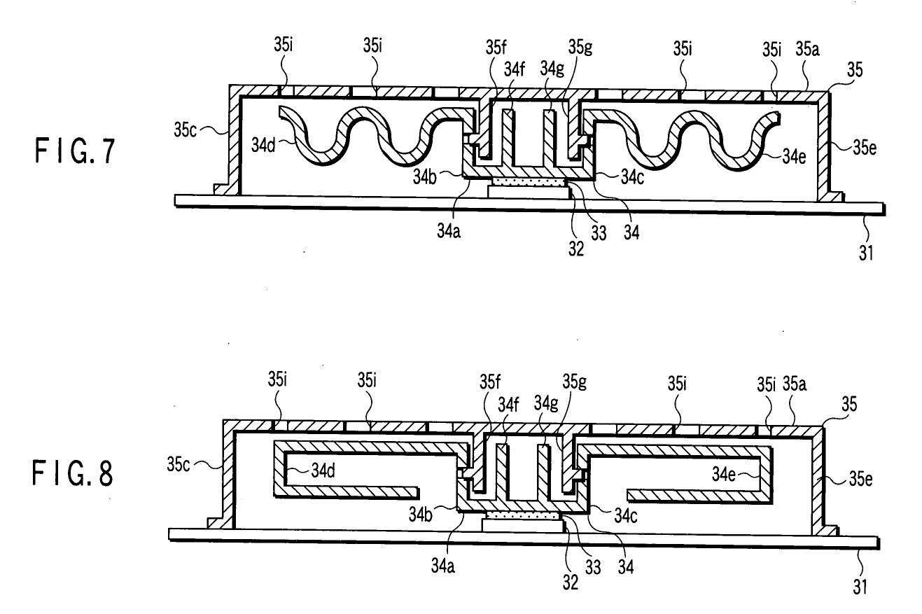

FIG. 7 shows a state that the heat dissipation plates 34d and 34e are bent in a curved wave shape, respectively. When the clearance holes 35i are formed to the portions of the flat plate 35a of the shield case 35 where the heat dissipation plates 34d and 34e disposed in the vicinities thereof, the heat dissipation effect can be enhanced also in this case.

Further, FIG. 8 shows a state that the heat dissipation plates 34d and 34e are bent in a rectangular shape, respectively. When the clearance holes 35i are formed to the portions of the flat plate 35a of the shield case 35 where the heat dissipation plates 34d and 34e are in the vicinities thereof, the heat dissipation effect can be also enhanced.

Although it is preferable that the heat dissipation plates 34d and 34e of the heat sink 34 be formed in symmetric shapes across the base plate 34a, it is needless to say that they may be formed in asymmetric shapes across the base plate 34a depending on the mounting state and the like of the circuit components on the circuit board 31.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A heat dissipation device for electronic equipment, comprising:
a circuit board on which a circuit component is mounted;
a heat conduction sheet attached to the circuit component;
a shield case which covers the surface of the circuit board including the circuit component and has a flat plate which is approximately parallel to the surface of the circuit board and to which fixing plates which project from positions of the flat plate corresponding to the circuit component toward the circuit board are formed; and
a heat sink attached to the fixing plates of the shield case, coming into contact with the heat conduction sheet when the surface of the circuit board is covered by the shield case, and including bent heat dissipation plates to be accommodated in the shield case.

2. A heat dissipation device for electronic equipment according to claim 1, wherein the shield case forms the fixing plates by bending a part of the flat plate.

3. A heat dissipation device for electronic equipment according to claim 1, wherein a cutout portion is formed to the flat plate of the shield case to expose the heat sink attached to the fixing plates to the outside.

4. A heat dissipation device for electronic equipment according to claim 1, wherein the shield case includes a pair of fixing plates formed approximately parallel to each other,
the heat sink has side plates confronting the surfaces of the fixing plates, respectively; and
the heat sink is attached to the shield case by engaging any ones of recessed portions and projecting portions formed to the respective side plates with the others of projecting portions and recessed portions formed to the respective fixing plates.

5. A heat dissipation device for electronic equipment according to claim 1, wherein the heat dissipation plates of the heat sink are bent in any shape of a triangular wave shape, a rectangular wave shape, a curved wave shape, and a rectangular shape.

6. A heat dissipation device for electronic equipment according to claim 1, wherein clearance holes are formed to the flat plate of the shield case in the portions where the heat dissipation plates are in the vicinities thereof.

7. A heat dissipation device for electronic equipment according to claim 1, wherein the heat sink has a base plate which comes into contact with the heat conduction sheet when the surface of the circuit board is covered by the shield case, and
the heat dissipation plates are a pair of heat dissipation plates formed integrally with the base plate and extending in an opposite direction with respect to the base plate.

8. A heat dissipation device for electronic equipment according to claim 7, wherein the pair of heat dissipation plates are formed in shapes that are symmetric across the base plate.

9. A heat dissipation device for electronic equipment according to claim 7, wherein the pair of heat dissipation plates are formed in shapes that are asymmetric across the base plate.

10. A heat dissipation device for electronic equipment comprising:
a circuit board formed in a flat shape;
a flat-shaped circuit component attached to the circuit board such that one surface of the circuit component confronts one surface of the circuit board;
a heat conduction sheet composed of a flexible material and attached to the surface of the circuit component opposite to the surface thereof confronting the circuit board;
a heat sink formed integrally of a base plate in contact with the heat conduction sheet, first side plates extending from ends of the base plate vertically with respect to the surface of the base plate, and heat dissipation plates extending from ends of the first side plates and bent in a predetermined shape; and
a shield case which accommodates the heat sink therein and covering the surface of the circuit board formed integrally of a flat plate disposed approximately parallel to the surface of the circuit board, second side plates extending from the peripheral edges of the flat plate, and fixing plates which project from predetermined positions of the flat plate in the same direction as the second side plates and to which the first side plates of the heat sink are attached.

11. A heat dissipation method for electronic equipment, comprising:
a first step of attaching a heat conduction sheet to a circuit component mounted on a circuit board;
a second step of attaching a heat sink having bent heat dissipation plates to fixing plates which project from positions of a flat plate of a shield case approximately parallel to the surface of the circuit board toward the circuit board, wherein the positions correspond to the circuit component, and the shield case covers the circuit board including the circuit component; and
a third step of covering the circuit board by the surface of the shield case such that the heat sink is accommodated in the shield case and comes into contact with the heat conduction sheet.
